(19) United States
(12) Patent Application Publication
(10) Pub. No.: US 2026/0026356 A1
(43) Pub. Date: Jan. 22, 2026

(54) STACKED DIE PACKAGE WITH ELECTRICAL SHIELDING PLATE

(71) Applicant: Cypress Semiconductor Corporation, San Jose, CA (US)

(72) Inventors: Navas Khan ORATTI KALANDAR, Pflugerville, TX (US); Alfredo Perez, Pflugerville, TX (US); Joo Tham, Sunnyvale, CA (US)

(73) Assignee: Cypress Semiconductor Corporation, San Jose, CA (US)

(21) Appl. No.: 19/195,319

(22) Filed: Apr. 30, 2025

Related U.S. Application Data
(60) Provisional application No. 63/672,660, filed on Jul. 17, 2024.

(51) Int. Cl. H01L 23/552; H01L 23/00; H01L 25/00; H01L 25/18

(52) U.S. Cl. CPC H01L 23/552; H01L 24/32; H01L 24/48; H01L 24/73; H01L 25/18; H01L 25/50; H01L 2224/32225; H01L 2224/48227; H01L 2224/73265

(57) ABSTRACT

A semiconductor package structure includes a substrate with a substrate surface, a processing device electrically coupled to the substrate surface, one or more radio frequency integrated circuits (RFIC(s)) electrically coupled to the substrate surface, and a shield plate. The shield plate is disposed between the one or more RFIC(s) and the processing device and is configured to couple the one or more RFIC(s) to a package ground via one or more conductors. The package ground has a ground voltage associated with the semiconductor package structure.

### RELATED APPLICATIONS

This application claims the benefit of Provisional Application No. 63/672,660, filed Jul. 17, 2024, which is incorporated by reference in its entirety.

### TECHNICAL FIELD

Aspects and implementations of the present disclosure relate to die packages, and more specifically to a stacked die package with electrical shielding plate.

### BACKGROUND

A die package (e.g., a semiconductor package structure) is an assembled form of an integrated circuit (IC). The die package may provide mechanical protection, electrical connections, and other features for the IC. The die package enables the IC to safely integrate into electronic systems, such as printed circuit boards (PCBs). The die package may include one or more ICs in the final configuration.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1A is a schematic block diagram of an example semiconductor package structure, including a spacer and a lead frame, according to some embodiments.

FIG. 1B is a schematic block diagram of an example semiconductor package structure, including a spacer and a laminate substrate, according to some embodiments.

FIG. 1C is a schematic block diagram of top-down perspective of an example semiconductor package structure according to some embodiments.

FIG. 2A is a schematic block diagram of an example semiconductor package structure, including a spacer and a lead frame, according to some embodiments.

FIG. 2B is a schematic block diagram of an example semiconductor package structure, including a spacer and a laminate substrate, according to some embodiments.

FIG. 3A is a schematic block diagram of an example semiconductor package structure, including a memory device and a lead frame, according to some embodiments.

FIG. 3B is a schematic block diagram of an example semiconductor package structure, including a memory device and a laminate substrate, according to some embodiments.

FIG. 4 is a schematic block diagram of an example semiconductor package structure, including a dual-sided substrate, according to some embodiments.

FIG. 5A is a schematic block diagram of a single-sided shield plate with a single ground plane according to one embodiment.

FIG. 5B is a schematic block diagram of a dual-sided shield plate with two ground planes according to some embodiments.

FIG. 6 depicts a flow diagram of an example method of manufacturing a semiconductor package structure according to some embodiments.

### DETAILED DESCRIPTION

In the context of microcontroller chip applications, such as those found in wearable devices, healthcare products, and home or industrial automation systems, there is a growing need for Bluetooth® and Wi-Fi® connectivity. However, integrating Bluetooth® and Wi-Fi® intellectual property (IP) blocks into a microcontroller unit (e.g., an MCU) system-on-chip (SoC) can be a resource-intensive and time-consuming process, potentially increasing development costs. One approach to expedite time to market, integrating a dedicated, standalone Bluetooth® and Wi-Fi® connectivity chip alongside the MCU within the same package, is recommended. This approach not only streamlines development but also facilitates quicker product launches.

Along with the growing demand for smaller and smaller wearable devices and other microcontroller chip applications comes a parallel growing demand for smaller and smaller die packages (e.g., semiconductor package structures). In order to efficiently use the available surface area of a microcontroller chip's substrate, integrated circuits (ICs) may be stacked on top of one another to form a stacked die package. Stacking a radio frequency (RF) chip that implements the Bluetooth® and Wi-Fi® technologies on an MCU chip provides the shortest die-to-die connections and a smaller package footprint, enabling the design of miniaturized products.

However, this stacking arrangement can introduce challenges related to electrical noise coupling, particularly when high-frequency RF chips that are sensitive to electromagnetic (EM) interference are involved. For example, a radio frequency integrated circuit (RFIC) is a type of IC designed to generate and transmit EM waves (e.g., radio waves) for wireless communication. RFICs are sensitive to EM radiation and can experience performance issues if exposed to external EM fields (e.g., from EM fields, waves, or radiation from another IC). Because other ICs, such as MCUs, emit EM fields through their operations, stacking an EM-sensitive IC (e.g., an RFIC) on an EM-emitting IC (e.g., an MCU) would result in the EM-sensitive IC experiencing performance issues related to electrical noise coupling. Such noise coupling can lead to reduced signal quality and potential malfunctions in the RFIC chip.

To avoid EM-sensitive ICs from experiencing such issues, they are conventionally placed in a side-by-side configuration with EM-emitting ICs. While this may diminish the performance issues experiences by the EM-sensitive IC, such a configuration often uses up to twice the available surface area of the substrate, resulting in larger die packages and wasted substrate surface area.

Aspects and embodiments of the present disclosure address these and other limitations of the existing technology by providing a stacked die package with electrical shielding plate. In some embodiments, the die package (e.g., the semiconductor package structure) includes a substrate, a processing device, one or more RFIC(s), and a shield plate. The processing device (e.g., an EM-emitting IC, such as an MCU) and the RFIC(s) (e.g., EM-sensitive ICs) may be electrically coupled to the substrate's surface. In some embodiments, the shield plate is arranged between the processing device and the RFIC(s) and configured to couple the RFIC(s) to the semiconductor package ground via conductors.

The systems, devices, and methods disclosed herein have advantages over conventional solutions. By placing the shield plate between the processing device and the RFIC(s), the EM-sensitive IC(s) are shielded from the EM emitted by the EM-emitting IC(s) to reduce performance issues, signal integrity problems, and/or instances of device failure. Placing the shield plate between the processing device and the RFIC(s) further enables the RFIC(s) to be stacked on the processing device, which reduces the amount of substrate surface area utilized by the die package. This decreases the overall size of the die package and reduces wasted substrate surface area.

Technologies directed to a stacked die package with electrical shielding plate are described in the present disclosure. The following description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure.

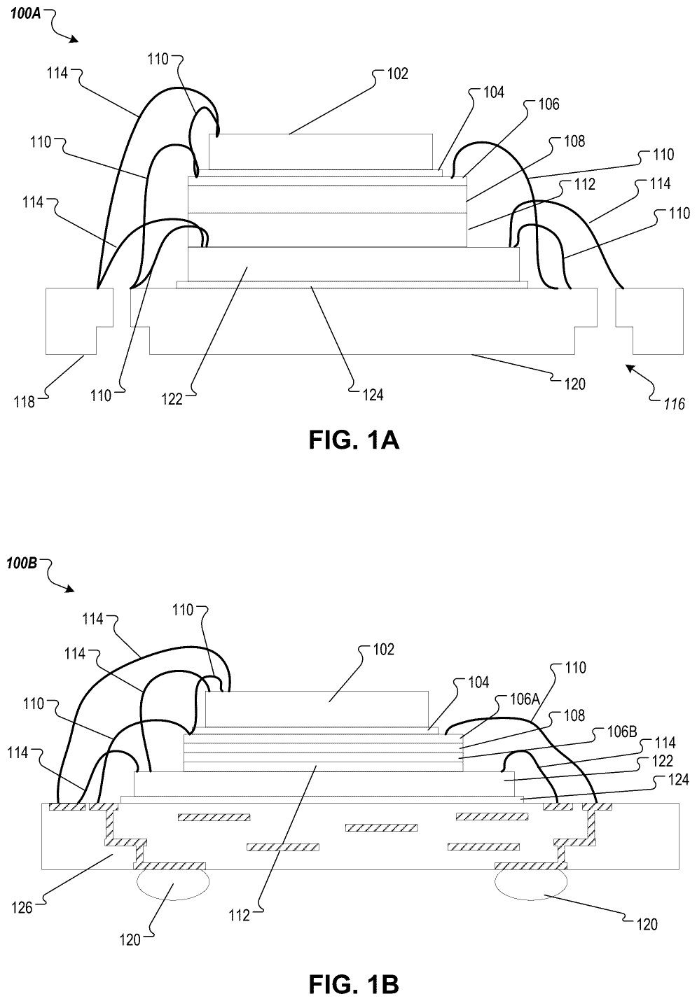

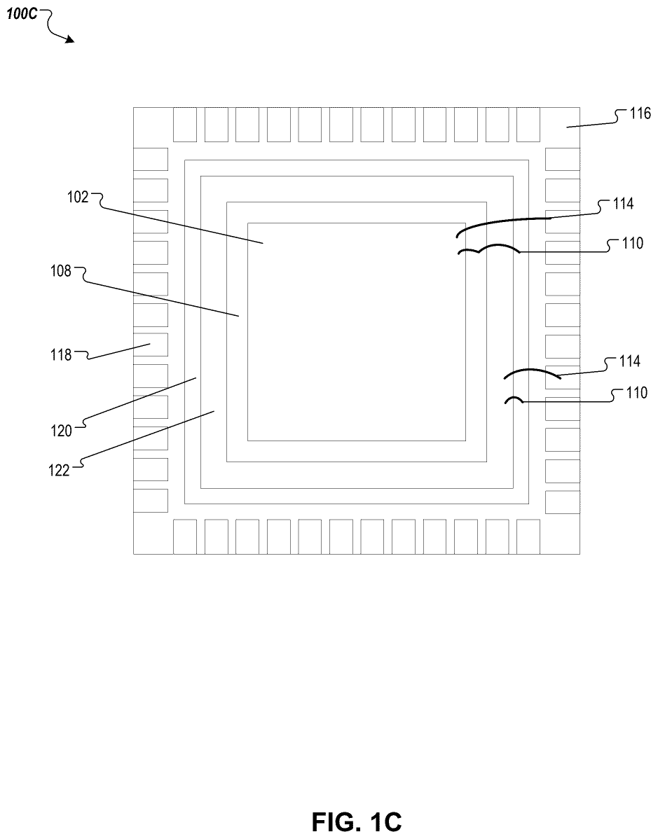

FIGS. 1A-B are schematic block diagrams of an example semiconductor package structure according to some embodiments. FIG. 1A is a schematic block diagram of an example semiconductor package structure 100A, including a lead frame 116, according to one embodiment. FIG. 1B is a schematic block diagram of an example semiconductor package structure 100B, including a laminate substrate 126, according to one embodiment. Both FIGS. 1A and 1B show substantially similar components, but with a different package substrate.

In some embodiments, the semiconductor package structure 100A is mounted on a lead frame 116 and includes one or more RFIC(s) 102, a shield plate 108, and a processing device 122. The components of the semiconductor package structure 100A may be attached to a package ground 120 of the lead frame 116 by a first die attach layer 124. A die attach layer may be used to physically bond the other components of the semiconductor package structure 100A to the lead frame 116 and may include materials such as adhesives (e.g., film adhesive, epoxy, etc.), solder, die attach films (DAFs), etc. In some embodiments, the die attach layer may be an epoxy that cures to a hard layer (e.g., resistant to penetration) to form a permanent joint. In other embodiments, the die attach layer may be a protective film (e.g., applied using a film over wire (FOW) technique) applied over the wire bonds that connect the components of the semiconductor package structure 100A to the substrate (e.g., the lead frame 116). The protective film may protect the wire bonds from mechanical stress, contamination, and/or moisture while maintaining the electrical integrity of the connections. The protective film may function as a spacer to physically separate various components of the semiconductor package structure 100A from the wire bonds of the various components.

The semiconductor package structure 100A may configure the various components (e.g., dies, ICs, etc.) is a stacked arrangement, such that one or more ICs may be stacked on another IC. In some embodiments, the first IC in such a stacked configuration may be the processing device 122. The processing device 122 may be a microcontroller unit (MCU), an application-specific integrated circuit (ASIC), a microprocessor unit (MPU), a field-programmable gate array (FGPA), etc. In some embodiments, the processing device 122 is a MCU secured to the package ground 120 via the first die attach layer 124. The MCU may be electrically coupled to the package ground 120 and one or more package leads 118 of the lead frame 116. In some embodiments, the MCU is electrically coupled to the package ground 120 via one or more ground connectors 110 and to the one or more package leads 118 via one or more signal and/or power connectors 114. The ground connectors 110 and/or the signal and/or power connectors 114 may be conductors (e.g., materials that allow electrical current flow).

In some embodiments, the shield plate 108 is positioned above and connected to the processing device 122 via a second die attach layer 112. The second die attach layer 112 may be a protective film to protect the wire bonds of the processing device 122 and allow the ground connectors 110 and/or the signal and/or power connectors 114 from the processing device 122 to pass through the second die attach layer 112. In some embodiments, the shield plate 108 includes a ground plane 106, which may be a layer of metal that electrically couples to the package ground 120 via one or more ground connectors 110. The ground plane 106 may, when connected to the package ground 120, function as a conductive pathway between the one or more RFIC(s) 102 and the package ground 120 to assist in reducing EM interference from the processing device 122. In some embodiments, the shield plate 108 is a silicon material (e.g., a silicon wafer), and the ground plane 106 is a metal layer of aluminum (Al) and/or copper (Cu). In some embodiments, the shield plate 108 may have more than one ground planes 106. A shield plate 108 having a single ground plane 106 may be referred to as a single-sided shield plate, and a shield plate 108 having more than one ground planes 106 may be referred to as a dual-sided shield plate.

The semiconductor package structure 100A may include one or more RFIC(s) 102 stacked on top of the shield plate 108. The shield plate 108 may be larger than the RFIC(s) 102 (e.g., has larger surface area than a single RFIC and/or multiple RFICs in a side-by-side configuration). In some embodiments, the one or more RFIC(s) 102 are attached to the ground plane 106 of the shield plate 108 via a third die attach layer 104, which may be made of a material substantially similar to the first die attach layer 124 and/or the second die attach layer 112. In some embodiments, the third die attach layer 104 is a different material from the first die attach layer 124 and/or the second die attach layer 112.

The RFIC(s) 102 may be electrically coupled to the ground plane 106 of the shield plate 108 via one or more ground connectors 110. Because the ground plane 106 is electrically connected (e.g., electrically coupled) to the package ground 120, the RFIC(s) 102 are further electrically coupled to the package ground 120 via ground connectors 110, according to some embodiments. The RFIC(s) 102 may be electrically coupled to the package ground 120 and one or more package leads 118 of the lead frame 116. In some embodiments, the RFIC(s) 102 are electrically coupled to the package ground 120 via one or more ground connectors 110 and to the one or more package leads 118 via one or more signal and/or power connectors 114.

The RFIC(s) 102 may be a short-range wireless communication IC (e.g., a Bluetooth® IC), a low-power short-range wireless communication IC (e.g., a Bluetooth® Low Energy (BLE) IC), a wireless local area network (WLAN) communication IC (e.g., a Wi-Fi® IC), a high-frequency IC (e.g., a millimeter wave IC), a photonic IC (e.g., an optical IC), or other various EM-sensitive ICs. In some embodiments, the RFIC(s) 102 is a single RFIC 102. In other embodiments, the RFIC(s) 102 are multiple RFICs. In embodiments with more than one RFIC 102 (e.g., a first RFIC and a second RFIC), the first RFIC and the second RFIC may be the same type of RFIC, or they may be different types of RFICs. The RFIC(s) 102 may be combined with other passive components, such as antennas, filters, etc. In some embodiments, the RFIC(s) 102 may include an integrated antenna structure. In other embodiments, the antenna may be separate from the RFIC(s) 102 and may be included in the semiconductor package structure 100A as an antenna module, and antenna-in-package (AiP), etc. If the antenna is separate from the RFIC(s) 102, the antenna may be stacked on top of the RFIC(s) 102 and/or in a side-by-side configuration with the RFIC(s) 102.

While the semiconductor package structure 100A includes the components described above in some embodiments, other components may be included in the semiconductor package structure 100A, such as resistors, capacitors, inductors, transformers, crystal oscillators, filters, antennae, varactor diodes, balanced-unbalanced transformer, etc.

FIG. 1B is a schematic block diagram of an example semiconductor package structure 100B, including a laminate substrate 126, according to some embodiments. The semiconductor package structure 100B is substantially similar to the semiconductor package structure 100A, with two exceptions.

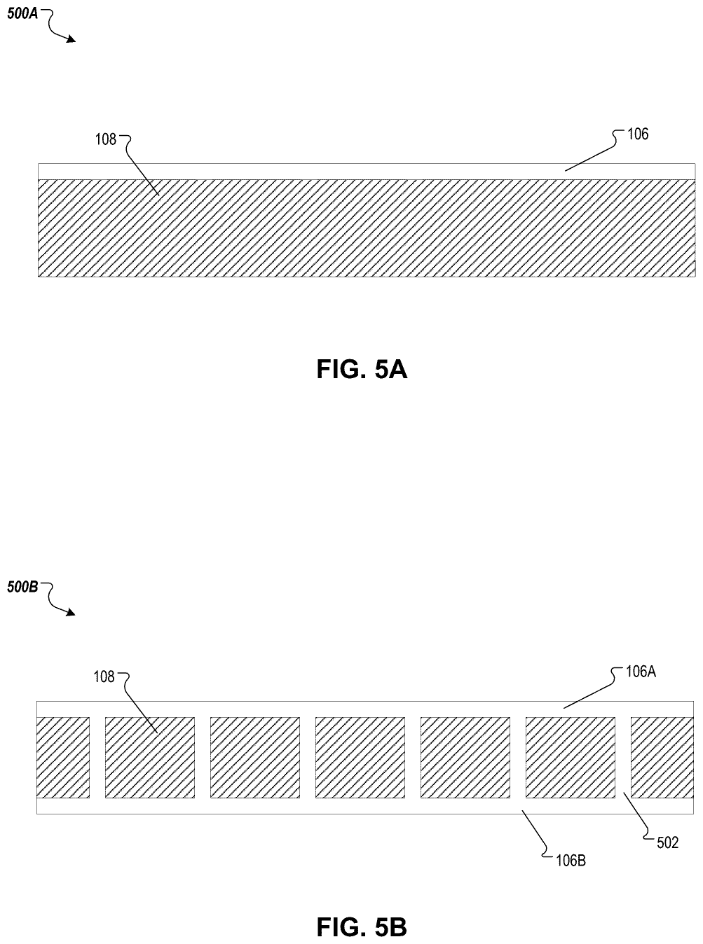

First, the shield plate 108 is a dual-sided shield plate and includes a first ground plane 106A and a second ground plane 106B in some embodiments. The shield plate 108 may be an organic material, such as bismaleimide-triazine (BT) resin, polyimide, liquid crystal polymer (LCP), polyethylene terephthalate (PET), etc. The first and/or second first ground planes 106A and 106B may be a metal layer of copper. In some embodiments, the metal layer may be of a metal sharing similar properties to copper, such as silver or gold. The first ground plane 106A and second ground plane 106B may be connected through the shield plate 108 by one or more vias (e.g., conductive pathway that connects different layers), as will be described in connection to FIG. 5B.

Second, the substrate on which the semiconductor package structure 100B is built is a laminate substrate 126. A laminate substrate may be a multilayered structure composed of alternating layers of insulating and conductive materials used in ball grid array (BGA) packages. BGA packages are surface-mounted IC packages with an array of solder balls on the underside of the package (e.g., opposite the semiconductor package structure 100B mounted on the top of the laminate substrate 126) that provide electrical and mechanical connections to the PCB. The conductive materials (e.g., traces) may extend from the top of the laminate substrate 126 to the solder balls to create a package ground 120. The one or more ground connectors 110 of the semiconductor package structure 100B may connect to the package ground 120 via these traces on the top of the laminate substrate 126. Other traces on the laminate substrate 126 may provide signal and/or power to the semiconductor package structure 100B via one or more signal and/or power connectors 114.

FIG. 1C is a schematic block diagram of top-down perspective of an example

semiconductor package structure 100C according to some embodiments. FIG. 1C shows substantially similar components as those illustrated in FIG. 1A, but from a different perspective (e.g., a top-down or overhead perspective).

In some embodiments, the semiconductor package structure 100C is mounted on a lead frame 116 and includes one or more RFIC(s) 102, a shield plate 108, and a processing device 122. The processing device 122 may be attached to the package ground 120 of the lead frame 116 by a first die attach layer and electrically connected to the package ground 120 and one or more package leads 118. The processing device 122 may be electrically connected to the package ground 120 by one or more ground connectors 110, and to the package leads 118 by one or more signal and/or power connectors 114. In some embodiments, the shield plate 108 is stacked on top of the processing device 122 and attached to the processing device 122 by a second die attach layer. The shield plate 108 may be a single-sided shield plate or a dual-sided shield plate.

The RFIC(s) 102 may be stacked on the shield plate 108 and attached to the shield plate 108 by a third die attach layer. The RFIC(s) 102 may be electrically connected to the shield plate 108 and/or the package ground 120 by one or more ground connectors 110. In some embodiments, the one or more ground connectors 110 are wire bonds, with a first wire bond to connect the one or more RFIC(s) 102 to the shield plate 108 and a second wire bond to connect the shied shield plate 108 to the package ground 120. The RFIC(s) 102 may also be electrically connected to the one or more package leads 118 by one or more signal and/or power connectors 114. In some embodiments, more than one RFIC 102 may be attached to the shield plate 108 in either a stacked or side-by-side configuration.

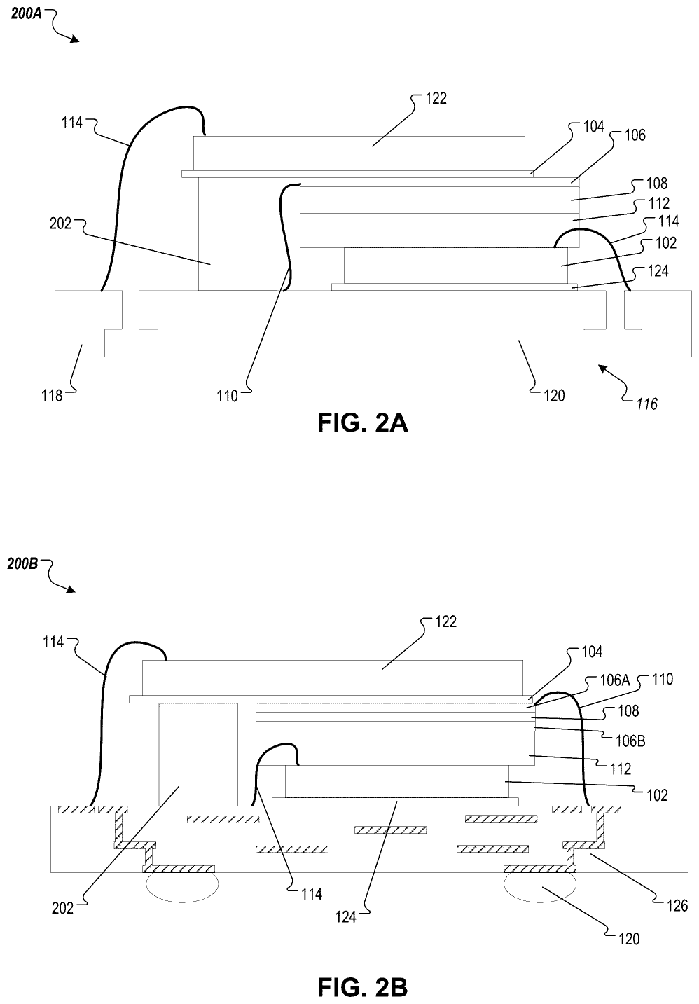

FIGS. 2A-B are schematic block diagrams of an example semiconductor package structure according to some embodiments. FIG. 2A is a schematic block diagram of an example semiconductor package structure 200A, including a spacer 202 and a lead frame 116, according to one embodiment. FIG. 2B is a schematic block diagram of an example semiconductor package structure 200B, including a spacer 202 and a laminate substrate 126, according to one embodiment. Both FIGS. 2A and 2B show substantially similar components as illustrated in FIGS. 1A-B, but with a different configuration.

In some embodiments, the semiconductor package structure 200A is mounted on a lead frame 116 and includes one or more RFIC(s) 102, a single-sided shield plate 108, a processing device 122, and a spacer 202. In some embodiments, the semiconductor package structure 200B is mounted on a laminate substrate 126 and includes one or more RFIC(s) 102, a dual-sided shield plate 108, a processing device 122, and a spacer 202. The RFIC(s) 102 may be attached to the package substrate (e.g., the lead frame 116 as illustrated in FIG. 2A or the laminate substrate 126 as illustrated in FIG. 2B) by the first die attach layer 124. The shield plate 108 may be stacked on top of the RFIC(s) 102 and attached to the RFIC(s) 102 by the second die attach layer 112. The shield plate 108 may be a single-sided shield plate (as illustrated in FIG. 2A) or a dual-sided shield plate (as illustrated in FIG. 2B). The processing device 122 may be stacked on top of the shield plate 108 and attached to the shield plate 108 by the third die attach layer 104.

In some embodiments, the spacer 202 is placed under the processing device 122 to provide structural support for the processing device 122. The spacer 202 may be made of a dielectric material (e.g., electrically insulating material), such as polyimide, silicon dioxide (SiO₂), epoxy resin, glass, silicon nitride (Si₃N₄), etc. The spacer 202 may be used to support the processing device 122 if the processing device 122 is larger than the RFIC(s) 102. In some embodiments, more than one spacer 202 may be used to support the processing device 122. In other embodiments, no spacer 202 may be used to support the processing device 122 (e.g., if the processing device 122 is smaller than the RFIC(s) 102).

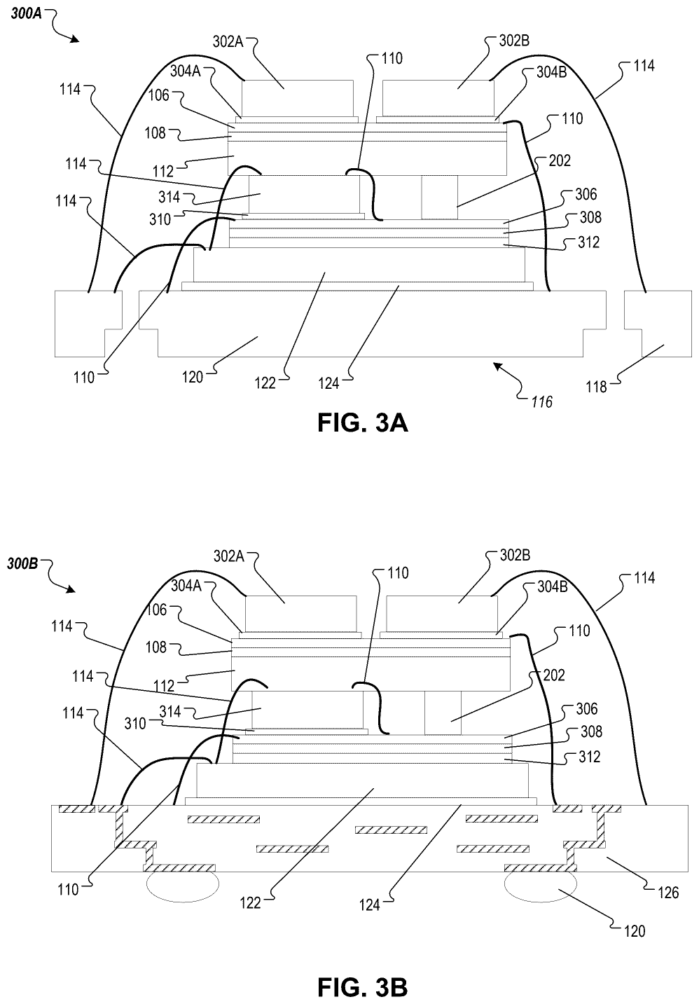

FIGS. 3A-B are schematic block diagrams of an example semiconductor package structure, including a memory device, according to some embodiments. FIG. 3A is a schematic block diagram of an example semiconductor package structure 300A, including a memory device 314 and a lead frame 116, according to one embodiment. FIG. 3B is a schematic block diagram of an example semiconductor package structure 300B, including a memory device 314 and a laminate substrate 126, according to one embodiment. Both FIGS. 3A and 3B show substantially similar components as illustrated in FIGS. 1A-B and 2A-B, but with a different configuration and additional component (e.g., the memory device 314).

In some embodiments, the semiconductor package structure 300A is mounted on a lead frame 116 and includes one or more RFIC(s) 102, a shield plate 108, a processing device 122, a memory device 314, and a memory device shield plate 308. In some embodiments, the semiconductor package structure 300B is mounted on a laminate substrate 126.

The processing device 122 may be attached to the package substrate (e.g., the 116 as illustrated in FIG. 3A or the laminate substrate 126 as illustrated in FIG. 3B) by the first die attach layer 124. The memory device shield plate 308 may be stacked on top of the processing device 122 and attached to the processing device 122 by the first memory device shield plate die attach layer 312. In some embodiments, the memory device shield plate 308 has a memory device ground plane 306 and is a single-sided shield plate. In other embodiments, the memory device shield plate 308 is a dual-sided shield plate. The memory device 314 may be attached to the memory device ground plane 306 of the memory device shield plate 308 by a second memory device shield plate die attach layer 310. Both the first memory device shield plate die attach layer 312 and the second memory device shield plate die attach layer 310 may be substantially similar to the first die attach layer 124, the second die attach layer 112, and/or the third die attach layer 104 described in relation to FIG. 1A.

In some embodiments, the memory device 314 is a memory die that stores data. The memory device 314 may be a volatile memory die (e.g., dynamic random-access memory (DRAM), static random-access memory (SRAM)), a non-volatile memory die (e.g., NAND Flash memory), or other type of memory die (e.g., high bandwidth memory (HBM), universal flash storage (UFS)). In some embodiments, a spacer 202 may also be stacked on the memory device ground plane 306 to provide support for the RFIC(s) 102 stacked above the memory device 314. The spacer 202 may be used to support the RFIC(s) 102 if the RFIC(s) 102 are larger than the memory device 314. In some embodiments, more than one spacer 202 may be used to support the RFIC(s) 102. In other embodiments, no spacer 202 may be used to support the RFIC(s) 102 (e.g., if the combined surface area of side-by-side RFIC(s) 102 is less than the surface area of the memory device 314, if the surface area of a single RFIC 102 is less than the surface area of the memory device 314).

The shield plate 108 may be attached to the memory device 314 and/or the spacer 202 by the second die attach layer 112. The shield plate 108 may further be attached to the RFIC(s) 102 by the third die attach layer 104. In some embodiments, more than one RFICs are arranged in a side-by-side configuration (e.g., a first RFIC 302A is coplanar with and adjacent to a second RFIC 302B). The first RFIC 302A may be attached to the ground plane 106 of the shield plate 108 by a first RFIC die attach layer 304A, and the second RFIC 302B may be attached to the ground plane 106 by a second RFIC die attach layer 304B. In some embodiments, the first RFIC 302A and the second RFIC 302B are both RFICs, such as a short-range wireless communication IC (e.g., a Bluetooth® IC), a low-power short-range wireless communication IC (e.g., a Bluetooth® Low Energy (BLE) IC), a wireless local area network (WLAN) communication IC (e.g., a Wi-Fi® IC), a high-frequency IC (e.g., a millimeter wave IC), a photonic IC (e.g., an optical IC), or other various EM-sensitive ICs. In some embodiments, either the first RFIC 302A or the second RFIC 302B is a different component, such as an antenna module.

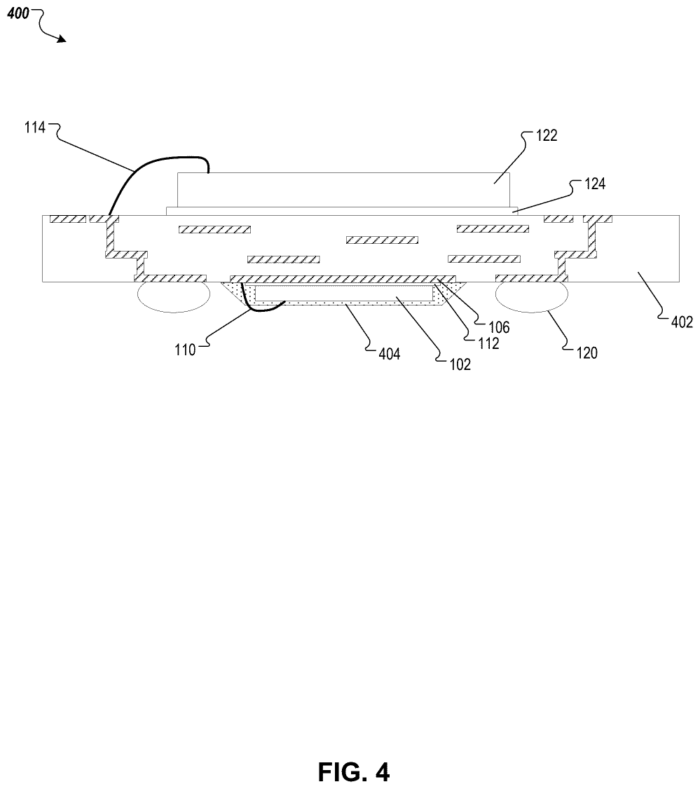

FIG. 4 is a schematic block diagram of an example semiconductor package structure 400, including a dual-sided substrate 402, according to some embodiments. The semiconductor package structure 400 is mounted on a dual-sided substrate 402 includes one or more RFIC(s) 102, a processing device 122, and a ground plane 106. The dual-sided substrate 402 may have a similar shielding effect as the shield plate 108 (e.g., of FIG. 1A), and the ground plane 106 may be integrated into (e.g., integral to) the dual-sided substrate 402.

In some embodiments, the processing device 122 is attached to a topside of the dual-sided substrate 402 by the first die attach layer 124. The RFIC(s) 102 may be attached to an underside of the dual-sided substrate 402 by the second die attach layer 112. In some embodiments, the semiconductor package structure 400 includes one RFIC 102 attached to the underside of the dual-sided substrate 402. In other embodiments, more than one RFIC 102 are attached to the underside of the dual-sided substrate 402 in either a stacked or side-by-side configuration.

The RFIC(s) 102 may be further attached to the underside of the dual-sided substrate 402 by an encapsulant 404. The encapsulant 404 may be a material such as an epoxy, which both attaches the RFIC(s) 102 to the underside of the dual-sided substrate 402 and encases the wires and/or wire bonds to improve electrical connectivity.

FIGS. 5A-B are schematic block diagrams of a shield plate according to some

embodiments. FIG. 5A is a schematic block diagram of a single-sided shield plate 500A with a single ground plane 106 according to one embodiment. FIG. 5B is a schematic block diagram of a dual-sided shield plate 500B with two ground planes 106A-B according to one embodiment. Both FIGS. 5A and 5B show substantially similar components as those illustrated in FIGS. 1A and 1B, but from a cross-section perspective.

In some embodiments, the shield plate 108 is a single-sided shield plate 500A, as illustrated in FIG. 5A, with a single ground plane 106 disposed on a first side of the shield plate 108. The shield plate 108 may be made of a silicon material. In other embodiments, the shield plate 108 is a dual-sided shield plate 500B, as illustrated in FIG. 5B. The dual-sided shield plate 500B may have a first ground plane 106A disposed on a first side of the shield plate 108 and a second ground plane 106B disposed on a second side of the shield plate 108. In some embodiments, the shield plate 108 may include an insulating layer made of an organic material. The first ground plane 106A and the second ground plane 106B may be connected to one another by one or more vias 502. In some embodiments, the vias 502 are through-silicon vias (TSVs).

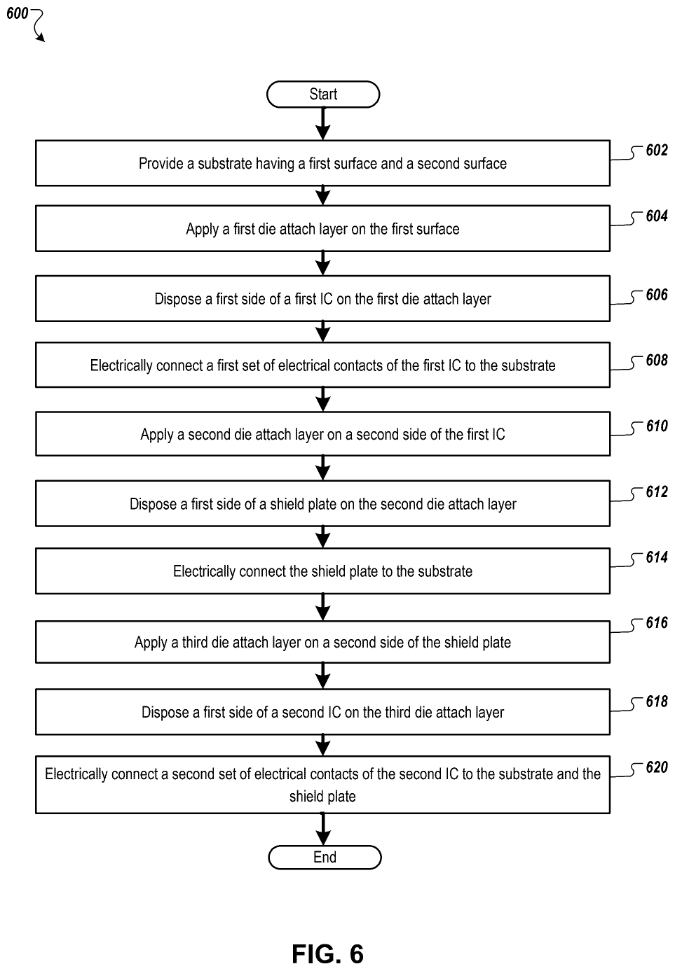

FIG. 6 depicts a flow diagram of an example method 600 of manufacturing a semiconductor package structure according to some embodiments. The method 600 may be performed by a variety of semiconductor package manufacturing equipment, such as a wafer dicing saw, a die attach machine, a wire bonder, a ball placement machine, encapsulation molding equipment, a wafer bonding machine, a plasma cleaner, TSV etching equipment, etc. Although shows in a particular sequence or order, unless otherwise specified, the order of the process can be modified. Thus, the illustrated embodiments should be understood as examples, and the illustrated process can be performed in a different order, and some processed can be performed in parallel. Other process flows are possible.

At operation 602, a substrate having a first surface and a second surface is provided. The substrate may be a package ground of a lead frame, a laminate substrate, a dual-sided substrate, or another type of substrate. The first surface may be a topside of the substrate, and the second surface may be an underside of the substrate. In some embodiments, the substrate includes a set of conductive traces for electrical routing (e.g., connecting various components within the semiconductor package structure).

At operation 604, a first die attach layer is applied to the first surface of the substrate. In some embodiments, the first die attach layer is applied on a first side of a first IC (e.g., a processing die, a processing device).

At operation 606, the first side of the first IC is disposed on the first die attach layer. The first IC may have a first set of electrical contacts. In some embodiments, the first IC is a processing device (e.g., an MCU). In some embodiments, the first IC includes one or more RFIC(s).

At operation 608, a first set of electrical contacts of the first IC is electrically connected to the substrate.

At operation 610, a second die attach layer is applied on a second side of the first IC. In some embodiments, the second die attach layer is applied on a first side of a shield plate. The second die attach layer may cover one or more wires of the first IC. In some embodiments, the one or more wires are wire bonds. In some embodiments, the one or more wires may extend through the second die attach layer (e.g., to connect to the substrate).

At operation 612, the first side of the shield plate is disposed on the second die attach layer. In some embodiments, the shield plate has a first ground plane and a second ground plane, and the second ground plane is disposed on the second die attach layer. The shield plate may include an insulating layer made of an organic material, with the first ground plane on a first side of the insulating layer and the second ground plane on a second side of the insulating layer. The first ground plane may be connected (e.g., electrically connected, electrically coupled) to the second ground plane by one or more vias extending through the insulating layer. In some embodiments, the first and second ground planes are a metal layer of copper. At operation 614, the shield plate is electrically connected to the substrate.

At operation 616, a third die attach layer is applied on a second side of the shield plate. In some embodiments, the third die attach layer is applied on a first side of a second IC. In some embodiments, the shield plate has a single ground plane, and the third die attach layer is applied on the ground plane. The shield plate may be a silicon material, and the ground plane may be a metal layer of aluminum or copper.

At operation 618, the first side of the second IC is disposed on the third die attach layer. The second IC may have a second set of electrical contacts. In some embodiments, the second IC includes one or more RFIC(s). In some embodiments, the second IC is a processing device. In some embodiments, the second IC is a memory device. In some embodiments, the one or more RFIC(s) includes a first RFIC and a second RFIC. The first RFIC may be coplanar with and adjacent to the second RFIC. In some embodiments, the first RFIC and the second RFIC are in a stacked configuration.

At operation 620, the second set of electrical contacts of the second IC is electrically connected to the substrate and to the shield plate.

In some embodiments, the methods, components, and features described herein are implemented by discrete hardware components or are integrated in the functionality of other hardware components such as ASICS, FPGAs, DSPs, or similar devices. In some embodiments, the methods, components, and features are implemented by firmware modules or functional circuitry within hardware devices. In some embodiments, the methods, components, and features are implemented in any combination of hardware devices and computer program components, or in computer programs.

To the extent that the terms “comprises,” “comprising,” “includes,” “including,” “has,” “contains,” variants thereof, and other similar words are used in either the detailed description or the claims, these terms are intended to be inclusive in a manner similar to the term “comprising” as an open transition word without precluding any additional or other elements.

As used in this application, the terms “block,” “layer,” “component,” “module,” “system,” or the like are generally intended to refer to a computer-related entity, either hardware (e.g., a circuit), software, a combination of hardware and software, or an entity related to an operational machine with one or more specific functionalities. For example, a component can be, but is not limited to being, a process running on a processor (e.g., digital signal processor), a processor, an object, an executable, a thread of execution, a program, and/or a computer. By way of illustration, both an application running on a controller and the controller can be a component. One or more components can reside within a process and/or thread of execution, and a component can be localized on one computer and/or distributed between two or more computers. Further, a “device” can come in the form of specially designed hardware; generalized hardware made specialized by the execution of software thereon that enables hardware to perform specific functions (e.g., generating interest points and/or descriptors); software on a non-transitory computer-readable medium; or a combination thereof.

The aforementioned systems, circuits, modules, and so on have been described with respect to interaction between several components and/or blocks. It can be appreciated that such systems, circuits, components, blocks, and so forth can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components can be combined into a single component providing aggregate functionality or divided into several separate sub-components, and any one or more middle layers, such as a management layer, can be provided to communicatively couple to such sub-components in order to provide integrated functionality. Any components described herein can also interact with one or more other components not specifically described herein but known by those of skill in the art.

Unless specifically stated otherwise, terms such as “identifying,” “receiving,” “causing,” “training,” “generating,” “providing,” “obtaining,” “interrupting,” “determining,” “transmitting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein or includes a general-purpose computer system selectively programmed by a computer program stored in the computer system. Such a computer program is stored in a computer-readable tangible storage medium.

Some of the methods and illustrative examples described herein are not inherently related to any particular computer or other apparatus. In some embodiments, various general-purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

The terms “over,” “under,” “between,” “disposed on,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

The words “example” or “exemplary” are used herein to mean serving as an example, instance or illustration. Any aspect or design described herein as “example’ or “exemplary” is not necessarily to be construed as preferred or advantageous over other aspects or designs. Rather, use of the words “example” or “exemplary” is intended to present concepts in a concrete fashion.

Reference throughout this specification to “one embodiment,” “an embodiment,” or “some embodiments” means that a particular feature, structure, or characteristic described in connection with the embodiment is included in at least one embodiment. Thus, the appearances of the phrase “in one embodiment,” “in an embodiment,” or “in some embodiments” in various places throughout this specification are not necessarily all referring to the same embodiment. In addition, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Also, the terms “first,” “second,” “third,” “fourth,” etc. as used herein are meant as labels to distinguish among different elements and can not necessarily have an ordinal meaning according to their numerical designation. When the term “about,” “substantially,” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A semiconductor package structure comprising:
a substrate comprising a substrate surface;
a processing device electrically coupled to the substrate surface;
one or more radio frequency integrated circuits (RFIC(s)) electrically coupled to the substrate surface; and
a shield plate, wherein the shield plate is disposed between the one or more RFIC(s) and the processing device, and wherein the shield plate is configured to couple the one or more RFIC(s) to a package ground having a ground voltage associated with the semiconductor package structure via one or more conductors.

2. The semiconductor package structure of claim 1, wherein the processing device is a microcontroller unit (MCU).

3. The semiconductor package structure of claim 1, wherein the one or more RFIC(s) is positioned above the processing device.

4. The semiconductor package structure of claim 1, wherein the one or more RFIC(s) are one of a short-range wireless communication integrated circuit (IC), a low-power short-range wireless communication IC, a wireless local area network (WLAN) communication IC, a high-frequency IC, or a photonic IC.

5. The semiconductor package structure of claim 1, wherein the shield plate is a silicon wafer that further comprises:
a first surface coupled to the processing device via an epoxy; and
a second surface coupled to a ground plane, wherein the ground plane is one of aluminum or copper.

6. The semiconductor package structure of claim 1, wherein the shield plate further comprises:
an insulating layer comprising an organic material, wherein the insulating layer has a first surface and a second surface;
a first ground plane disposed on the first surface of the insulating layer;
a second ground plane disposed on the second surface of the insulating layer; and
one or more vias extending through the insulating layer and electrically coupling the first ground plane and the second ground plane, wherein the first ground plane and the second ground plane is copper.

7. The semiconductor package structure of claim 1, wherein a first RFIC of the one or more RFIC(s) is configured to be coplanar and adjacent to a second RFIC of the one or more RFIC(s), and wherein the first RFIC and the second RFIC are positioned above the processing device.

8. The semiconductor package structure of claim 1 further comprising a memory device disposed between the one or more RFIC(s) and the processing device, wherein the shield plate is disposed between the memory device and the processing device, and wherein a second shield plate is disposed between the memory device and the one or more RFIC(s).

9. The semiconductor package structure of claim 1, wherein an antenna module is disposed on the one or more RFIC(s), and wherein there is no shield plate between the one or more RFIC(s) and the antenna module.

10. The semiconductor package structure of claim 1, wherein the shield plate is configured to:
couple to the package ground of the semiconductor package structure via one or more first wire bonds; and
couple to the one or more RFIC(s) via one or more second wire bonds, wherein the shield plate is configured to electrically couple the one or more RFIC(s) and the package ground via the one or more first wire bonds and the one or more second wire bonds.

11. A semiconductor package structure comprising:
a dual-sided substrate comprising a first surface and a second surface;
a processing device electrically coupled to the first surface of the substrate;
one or more RFIC(s) electrically coupled to the second surface of the substrate positioned below the processing device; and
a shield plate, wherein the shield plate is disposed between the one or more RFIC(s) and the processing device, and wherein the shield plate is configured to couple the one or more RFIC(s) to a ground voltage associated with the semiconductor package structure via one or more conductors.

12. The semiconductor package structure of claim 11, wherein the one or more RFIC(s) are one of a short-range wireless communication IC, a low-power short-range wireless communication IC, a wireless local area network (WLAN) communication IC, a high-frequency IC, or a photonic IC.

13. The semiconductor package structure of claim 11, wherein the shield plate is integral to the dual-sided substrate.

14. The semiconductor package structure of claim 11, wherein a first RFIC of the one or more RFIC(s) is configured to be coplanar and adjacent to a second RFIC of the one or more RFIC(s).

15. The semiconductor package structure of claim 11, wherein a first RFIC of the one or more RFIC(s) is configured to be disposed above a second RFIC of the one or more RFIC(s).

16. A method of manufacturing a semiconductor package structure comprising:
providing a substrate having a first surface and a second surface, wherein the substrate comprises a plurality of conductive traces for electrical routing;
applying, on the first surface of the substrate, a first die attach layer;
disposing a first side of a first IC on the first die attach layer, wherein the first IC has a first set of electrical contacts;
electrically connecting the first set of electrical contacts of the first IC to the substrate;
applying, on a second side of the first IC, a second die attach layer configured to cover one or more wire bonds of the first IC;
disposing, on the second die attach layer, a first side of a shield plate;
electrically connecting the shield plate to the substrate;
applying, on a second side of the shield plate, a third die attach layer;
disposing a first side of a second IC on the third die attach layer, wherein the second IC has a second set of electrical contacts; and
electrically connecting the second set of electrical contacts of the second IC to the substrate and to the shield plate.

17. The method of claim 16, wherein the first IC is an MCU.

18. The method of claim 16, wherein the second IC is one or more RFIC(s).

19. The method of claim 18, wherein a first RFIC of the one or more RFIC(s) is configured to be coplanar and adjacent to a second RFIC of the one or more RFIC(s), and wherein the first RFIC and the second RFIC are positioned above the first IC.

20. The method of claim 16, wherein the shield plate further comprises:
an insulating layer comprising an organic material, wherein the insulating layer has a first surface and a second surface;
a first ground plane disposed on the first surface of the insulating layer;
a second ground plane disposed on the second surface of the insulating layer; and
one or more vias extending through the insulating layer and electrically coupling the first ground plane and the second ground plane, wherein the first ground plane and the second ground plane is copper.
